(19) United States
(12) Patent Application Publication
(10) Pub. No.: US 2023/0182233 A1
(43) Pub. Date: Jun. 15, 2023

(54) Determining a Radiation Intensity and/or a Wavelength of Process Lighting

(71) Applicant: Siemens Aktiengesellschaft, München (DE)

(72) Inventor: Frank Heinrichsdorff, Teltow (DE)

(73) Assignee: Siemens Aktiengesellschaft, München (DE)

(21) Appl. No.: 17/920,117

(22) PCT Filed: Mar. 3, 2021
(86) PCT No.: PCT/EP2021/058239

§ 371 Date: Oct. 20, 2022

(30) Foreign Application Priority Data
Apr. 21, 2020 (EP) 20170681.9

(51) Int. Cl. B23K 26/06; G01J 9/00; G01J 1/42; B23K 26/342; B22F 10/36; B22F 10/85; B33Y 50/02

(52) U.S. Cl. CPC B23K 26/0626; G01J 9/00; G01J 1/42; B23K 26/342; B22F 10/36; B22F 10/85; B33Y 50/02; B22F 10/28

(57) ABSTRACT

Various embodiments of the teachings herein include a method for determining a radiation intensity and/or a wavelength of a process light, wherein the melt pool underlying the process light can be generated by irradiating a metal material with an energy beam along a path, wherein the energy beam can be moved in accordance with a power profile along the path. The method may include:
providing a power profile for a section of the path as an input variable for a machine learning model; training the model using historical and/or synthetic power profiles and associated historical or synthetic radiation intensities and/or wavelengths of the process light for the metal material; and determining the radiation intensity and/or the wavelength of the process light as an output variable of the model.

### CROSS-REFERENCE TO RELATED APPLICATIONS

This application is a U.S. National Stage Application of International Application No. PCT/EP2021/058239 filed Mar. 30, 2021, which designates the United States of America, and claims priority to EP Application No. 20170681.9 filed Apr. 21, 2020, the contents of which are hereby incorporated by reference in their entirety.

### TECHNICAL FIELD

The present disclosure relates to melting processes. Various embodiments may include method and/or systems for determining a radiation intensity and/or a wavelength of process light, for determining process deviations of a melting process, and/or for closed-loop control of a melting process.

### BACKGROUND

In powder-bed-based AM installations, process light (emission in visible and near infrared) is being increasingly ascertained for process monitoring. For this purpose, coaxial sensors (for example: “melt pool monitoring” via photo diodes) or spatially resolved (cameras), which are mounted in the installation space, or integrated sensors (photo diodes, pyrometers) are used. Since there is no known target value for the location-dependent emission in advance, (this must depend both on the process parameters and also on the exposed geometry), it is possible to use as an indicator for a process anomaly a deviation of the detected intensity from an average value by a statistically determined amount (for example 1×sigma, 3×sigma). This means that the detection limit is defined by the statistical and systematic variance of the signals. In practice, it is consequently difficult to reliably recognize process deviations.

### SUMMARY

The teachings of the present disclosure may improve the determination of a radiation intensity and/or a wavelength of process light of a melting process and/or improve the determination of process deviations in the case of such a melting process and to control said melting process in a closed-loop manner. For example, some embodiments include a method for determining a radiation intensity and/or a wavelength of a process light (E10), wherein the melt pool (10) underlying the process light (E10) can be generated by irradiating a metal material (20) with an energy beam (50) along at least one path (x), wherein the energy beam (50) can be moved in accordance with a power profile (P) along the path (x), comprising: providing the power profile (P) for a section (dtPOI) of the path (x) as an input variable (IN) for a machine learning model (MLM), in particular for a neural network, wherein the model (MLM) is trained using historical and/or synthetic power profiles (PH) and associated historical or synthetic radiation intensities (E10H) and/or wavelengths of the process light (E10) for the metal material (20), and determining the radiation intensity and/or the wavelength of the process light (E10) as an output variable (OUT) of the model (MLM).

In some embodiments, the method includes providing as an input variable for the model (MLM) at least one distance history (d) for the section (dtPOI), wherein the distance history (d) describes a distance between the section (dtPOI) and the position at which the radiation intensity and/or the wavelength of the process light (E10) is to be determined.

In some embodiments, the method includes providing as an input variable for the model (MLM) at least one mass profile (m) for the section (dtPOI), wherein the mass profile (m) describes a mass of the material (20) for each point on section (dtPOI).

In some embodiments, the method includes providing as an input variable for the model (MLM) at least one background temperature (T20) which the material or the workpiece has outside the melt pool.

In some embodiments, the model (MLM) has a topology having coefficients of regression.

In some embodiments, the method includes providing a volume element that is representative for the section (dtPOI) as an input variable (IN) for the model (MLM).

In some embodiments, the method includes providing as an input variable for the model (MLM) a workpiece geometry that is representative for the section (dtPOI).

In some embodiments, the section (xPOS) is selected so that at least one interruption of the energy beam (50) is included.

In some embodiments, the section (xPOS) is selected in dependence upon a workpiece geometry.

As another example, some embodiments include a method for determining process deviations (DEV) of a melting process, comprising: providing a target value (SET_E10) for a process light (E10) of a melt pool (10), wherein the target value (SET_E10) is determined by a radiation intensity that is determined in accordance with a method as claimed in one of the preceding claims and/or a wavelength of the process light (E10), detecting a radiation intensity, which is emitted by the melt pool (10), and/or a wavelength of the process light (E10) as an actual value (ACT_E10), and comparing the target value (SET_E10) with the actual value (ACT_I10), in order to detect process deviations (DEV).

In some embodiments, the relevance of the process deviation is weighted with the aid of classification parameters.

As another example, some embodiments include a method for the closed-loop control of a melting process, wherein a process deviation (DEV) that is determined by means of a method as described herein is reduced and/or eliminated by adapting one or multiple process parameters, in particular a beam power, a beam speed, a distance between individual exposure vectors.

### BRIEF DESCRIPTION OF THE DRAWINGS

The teachings herein are further described and explained below with the aid of exemplary embodiments that are illustrated in the figures. In the drawings:

FIG. 1 shows a schematic illustration of a material and an energy beam incorporating teachings of the present disclosure;

FIG. 2 shows a schematic illustration of the creation of input variables for a machine learning model incorporating teachings of the present disclosure;

FIG. 3 shows a machine learning model with its input variables incorporating teachings of the present disclosure; and

FIG. 4 shows a closed-loop control of an energy beam on the basis of the determined values for the process light incorporating teachings of the present disclosure.

### DETAILED DESCRIPTION

Some embodiments of the teachings herein include a method for determining a radiation intensity and/or a wavelength of process light. The melt pool underlying the process light is generated by irradiating a metal material with an energy beam along at least one path. The metal material lies in particular in a powder bed, in other words for example in the case of a powder bed-based additive manufacturing method, such as for example SLM. In this case, the energy beam can be moved in accordance with a power profile along the path.

In some embodiments, the method includes providing the power profile for a section of the path as an input variable for a machine learning model. In this case, the machine learning model is designed in particular as a neural network and is referred to in this case in English as a “machine learning model”. In this case, the model is trained using historical and/or synthetic power profiles and the associated historical or synthetic radiation intensities and/or wavelengths of the process light for the metal material. In a further step, the radiation intensity is now determined by the machine learning model as an output variable of the model.

In this case, the melt pool can be located, for example, in a powder bed, on a substrate or in a powder bed which is arranged on a substrate. In particular, the melt zone is located in a powder bed that is melted selectively and layer for layer in order to generate a workpiece. In the case of weld connections, the melt zone can form in a similar manner between two or multiple workpieces that are to be joined together.

In particular, models for supervised learning or part-supervised learning are used as machine learning models, since the input variables and output variables can for the most part be ascertained and approximated easily. In particular, the energy beam power (in other words for example the power that is adjusted at a laser of an SLM installation) can be easily ascertained here in conjunction with further process parameters, such as beam speed and beam path, which are often combined to form so-called exposure vectors. In the present case, neural networks, support vector machines, and random forest models (in general: decision trees) have proven to be particularly advantageous embodiments of the machine learning models. In so doing, the ML model for predicting the process light is used as a regressor and not for classification. However, combinations of different ML models—for example a model for determining the process light and a model for classifying the deviation of the process light from the target value are possible.

The power profile describes the power of the energy beam introduced in the section of the path. In this case, a position can be selected at which the process light is to be determined. In this case, the position can be part of the section. The section can likewise extend beyond the position, for example in that planned target values which follow the position are used.

The power profile can be determined from the adjusted energy beam power, in other words for example from the laser power. In this manner, it is possible, in a simple manner and with sufficient accuracy, for example while taking into consideration a reflexion portion of the energy beam at the material, to determine the power that is radiated onto the material and subsequently absorbed.

The historical power profile and the associated historical radiation intensities and/or wavelengths can be provided in this case from preceding measuring sequences. It is likewise feasible that for simple cases model-based power profiles using a model-based approach are converted into associated synthetic radiation intensities and/or wavelengths which are then used in turn for training the model. It has proven to be the case that a machine learning model that is trained using real data, for example a neural network, realizes a high degree of accuracy when determining the process light. In contrast to a simulation model, the trained model can in this case realize a considerable advantage with regard to calculation time. Likewise, existing non-linearities can be more efficiently imaged using a trained machine learning model.

The training is further explained using an example of pairing historical power profiles and the associated historical radiation intensities and/or wavelengths of the process light. In this case, the data pairing can be determined from individual layers of already completed build jobs or even from the first layers in a current build job. For this purpose, for example, a few layers that cover a broad application profile are selected. Layers in which an overhang and a solid structure are manufactured are suitable for such a pairing.

In this case, the pairing comprises for training purposes the power profiles as input variables in order to determine therefrom an anticipated process light. The measured process light of the pairing can then be compared with the anticipated process light in order to improve the model.

By way of example, a camera and/or a photodiode that use the same optics as the laser can be used as detectors for the radiation intensities and/or wavelengths. The measurement values of radiation intensities and/or wavelengths that are ascertained in this manner can then serve together with the power profiles as training data. In the trained state, the model can finally determine from a power profile as an input variable a process light as an output variable. If, during operation, the process light that is determined by the model is now compared with the process light that is actually measured as the actual value, then it is possible during live operation to immediately recognize statistical deviations of the process light.

In some embodiments, the method comprises providing as an input variable for the model at least one distance history for the section. The distance history describes in this case the distance between the respective data point on the section and the position at which the radiation intensity and/or the wavelength of the process light is to be determined. The distance history is designed as a function of time, alternatively the distance history could also be referred to as a distance transient. It is thus possible to more readily estimate how the power profile affects the respective melt pool, since the distance can thus be included as a weighting factor.

In some embodiments, the method comprises providing as an input variable for the model at least one mass profile for the section. The mass profile describes in this case the underlying mass for each data point of the power profile in order to realize a greater degree of accuracy of the heating of the melt pool and the accompanying change in the process light. In this case, the mass profile can be calculated as a mass integral over the geometry of the section of the path. For example, a hemisphere can be used as a volume below a point in the section. The point would then be the middle point of the hemisphere and the hemisphere extends into the already fabricated layer. The mass profile can also be described as a function of time.

In some embodiments, the model is trained using historical and/or synthetic power profiles and associated historical or synthetic radiation intensities and/or wavelengths of the process light for the metal material and for similar beam parameters. The training for similar beam parameters can be performed, for example, by already completed build jobs with the metal material and similar or identical beam/laser parameters (speed/power/focus). It is thus possible to further improve the trained model.

In some embodiments, a background temperature is provided as an input variable for the model. In this case, the background temperature is the temperature which serves as a base level for the model. In other words, the background temperature is the temperature that the material or the workpiece has. The accuracy of the method can be increased by using a background temperature. It is feasible that the background temperature follows a simple curve or assumes an averaged value. The background temperature is consequently the ambient temperature of the melt pool.

The background temperature can, however, in this case likewise originate from a superordinate simulation, which can be performed on the basis of a thermal CAD model of the workpiece that is to be manufactured or the weld seam that is to be produced. Furthermore, the background temperature can be provided for certain workpieces in dependence upon the irradiation duration and upon a preceding temperature. As a simple to determine background temperature, for example, in the thermally efficiently connected case, the background temperature could also be assumed to be the temperature to which the build panel is preheated.

In some embodiments, the machine learning model has a topology having coefficients of regression (also regression parameters or regression weights). It has proven to be the case that a topology having coefficients of regression produces very good results when the process light is imaged. In particular, multilayer neural networks with the typically used non-linear activation function or deep decision trees can sufficiently approximate even complex dependencies of the output variable (process light) on the relevant features (performance history, geometry, . . . ).

In some embodiments, a volume element that is representative for the section is provided as an input variable for the model. The volume element can in this case be extracted from a so-called job file or from a special contour file. In this case, these can be for example so-called discs, in other words slices, the geometries of which are taken into consideration for the section. The volume element can also be used in this case for the purpose of determining a representative mass.

In some embodiments, it is likewise feasible that a workpiece geometry that is representative for the section is provided as an input variable for the model, in particular from a CAD file. With the aid of the workpiece geometry in which the material is being processed, it is possible to recognize whether a critical geometry is involved here. If, for example, a tapering is being processed, then it can be expedient to consider the entire tapering until the melt pool has realized a sufficiently large distance from the tapering. Only if the distance of the melt pool from the tapering is sufficiently large, can it be concluded that the material in the region of the tapering is melting again. Thus, in this case, an accordingly large representative volume element should be selected or a volume element that, as long as the distance is not sufficiently large, comprises the tapering, in other words a critical site.

In some embodiments, the section is selected such that at least one interruption of the energy beam is included. The energy beam is guided in so-called exposure vectors over the workpiece or over the material. In order to change from one vector to the other, so-called skywriting times are planned. This means, the energy beam is deactivated, the position mechanisms, in other words for example the mirrors, re-positioned and the energy beam is re-activated at the start of the next vector or the next exposure track. Since these tracks lie adjacent to one another, it may be particularly advantageous to consider more than one of these tracks for which reason a selection of the section in the ideal case includes at least one interruption of the energy beam or multiple interruptions of the energy beam.

In some embodiments, the section is selected in dependence upon a further workpiece geometry. The length of the section can vary in this case depending upon the complexity of the workpiece geometry. In this case, it is possible for example to include adjacent exposure vectors in the section. Exposure vectors include in this case the coordinates in which the energy beam is guided over the material. Furthermore, the exposure vectors include the beam power and the speed with which the coordinates are traversed.

Some embodiments include a method for determining process deviations of a melting process. The method may comprise in this case: A target value for a process light of a melt pool is determined by a method in accordance with the invention for determining a radiation intensity and/or wavelength of the process light. A radiation intensity, which is emitted by the melt pool, and/or a wavelength of the process light is ascertained, in other words for example measured as an actual value. The target value is compared with the actual value in order to determine process deviations.

In this case, the process deviations are a measurement for the quality of the process and can be used in a further step for a closed-loop control of the process. It may be advantageous that as a target value a particularly precise value of the radiation intensity is determined in accordance with one or more of the methods incorporating teachings of the present disclosure and/or the wavelength of the process light is used. In comparison to using a deviation as an indicator for a process anomaly, for example a deviation of the detected intensity from an average value by a statistically determined (for example one times sigma or three times sigma), the value that is determined in accordance with the invention as a target value represents a considerable improvement.

In some embodiments, the relevance of the process deviation is weighted with the aid of classification parameters. The dimensions, the area or the volume of the relevant regions can serve as classification parameters in order to determine an appropriate reaction to the process deviation. Thus, a region that has a high mass and a fixed structure can withstand a different type of process deviations than a filigree region in which numerous fine structures are located in the region of the melt pool.

In other words, a method for detecting process anomalies or deviations may include:

1. A detection of distinctive regions by means of a target-actual comparison as described.

2. Examination of the relevance of the deviations/anomalies with the aid of, for example, geometric features such as dimensions, area or volume, where appropriate also by using a classification of the deviation or of the relevant region. If a value for the process light that is determined using teachings of the present disclosure is now used for determining process anomalies and as a result an improved target-actual comparison is realized. In lieu of the average value, a determined value is used as a target value for the process light. For this purpose, a machine learning model is trained using measured or synthetic process data in order, in dependence upon process parameters and geometry, to generate a prediction of the signal that is to be expected. The irradiated energy of the preceding exposure vectors in spatial and temporal proximity and preferably a mass integral that is derived from the geometry serve as input parameters for the prediction of the signal for a point of the exposed area. This creates a smaller variance of the target-actual difference compared to using an average value as a target value, and narrower detection limits can be set, whereby the reliability of the process error detection is improved.

Some embodiments include a method for the closed-loop control of a melting process. In this case, a process deviation that is determined as described above is reduced and/or eliminated, in that one or multiple process parameters, in particular a beam power, a beam speed or a distance between individual exposure vectors is varied.

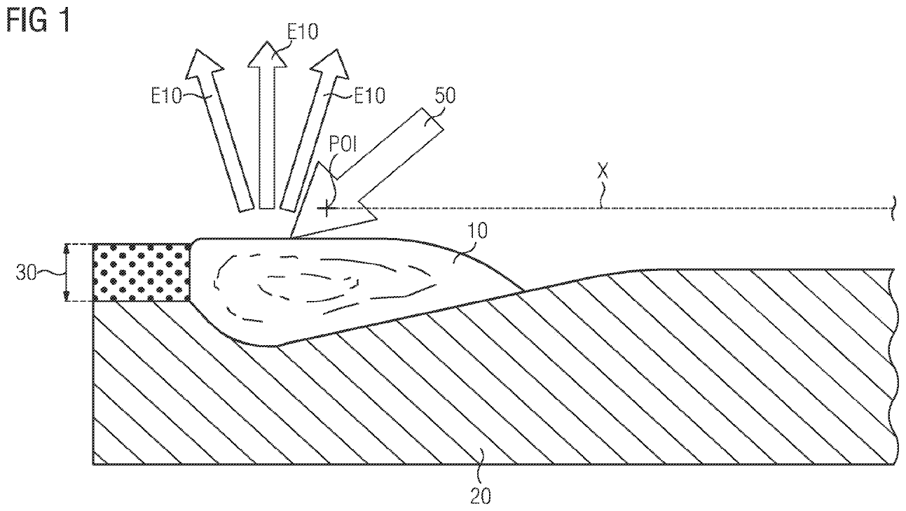

FIG. 1 illustrates in this case a schematic illustration of a material 20 on which a material 30 in powder form is applied. An energy beam 50 generates a melt pool 10 from which process light E10 emanates. In this case, the energy beam 50 is guided along a path x over the material 20. The material 20 can be in this case part of a workpiece that is manufactured by means of an additive manufacturing process using the energy beam 50. The energy beam 50 has in this case a beam power that is guided in a power profile P along the path x. Since a cross-section in the plane is illustrated, FIG. 1 does not illustrate further exposure tracks that are covered by the path x or exposure vectors that lie in the plane parallel to the path x, illustrated here. A position POI is determined above the melt pool 10 from which a temporal distance history d is defined with regard to other points along the path x. In this case, the position POI can lie in the melt pool 10 but it is illustrated here somewhat above said melt pool for reasons of clarity.

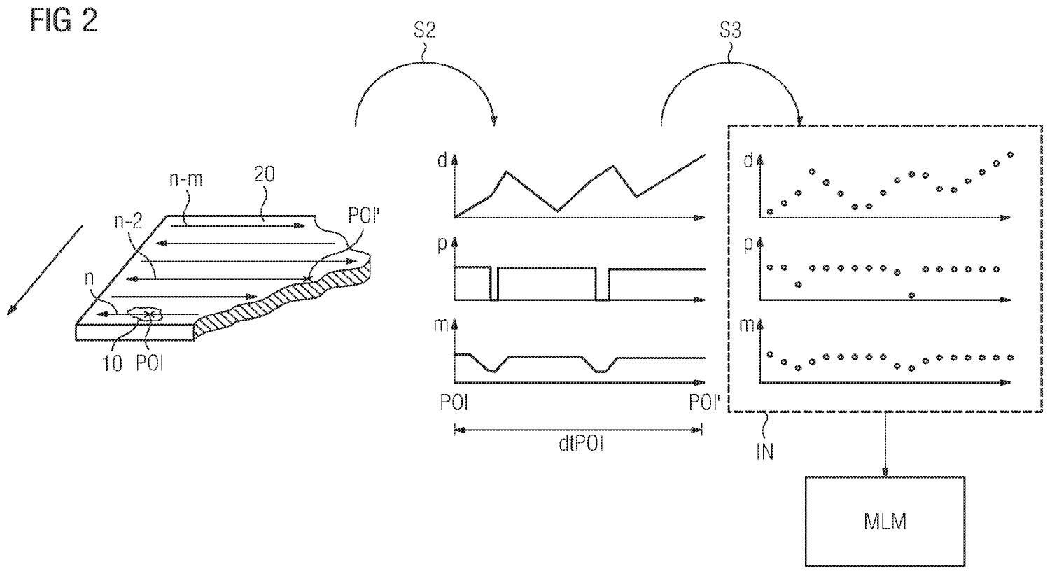

FIG. 2 illustrates initially the material 20 known from FIG. 1, wherein this is illustrated in an oblique view. Vectors n to n-m are imaged on the material 20, wherein the vectors n, . . . , n-m lie along the path x, which is not illustrated here for reasons of clarity. Furthermore, a position POI which lies inside the melt pool 10 is apparent. Furthermore, in order to form a section dtPOI, the start POI′ of the section dtPOI is illustrated. In this case, a first step S1 is to select the section dtPOI. The section dtPOI is preferably here in a time-based manner. In a second step S2, a local history from the start POI′ of the section dtPOI as far as the position POI is generated for the section dtPOI.

This local history comprises in this case a distance history d that describes the distance of each data point to the vectors n, n-m or along the path x to the position POI. Furthermore, a power profile is created, which describes the power that is radiated by the energy beam 50. A mass profile m describes the mass underlying at the respective data point and said mass can be determined, for example, for a volume element and an integration over it. In a step S3, the generated local history, in other words the distance history d, the power profile P and the mass profile m are discretized or integrated. This is advantageously performed on a solid and where appropriate non-equidistant raster. Consequently, the now discretized available data can be used as input variables IN for a machine learning model MLM.

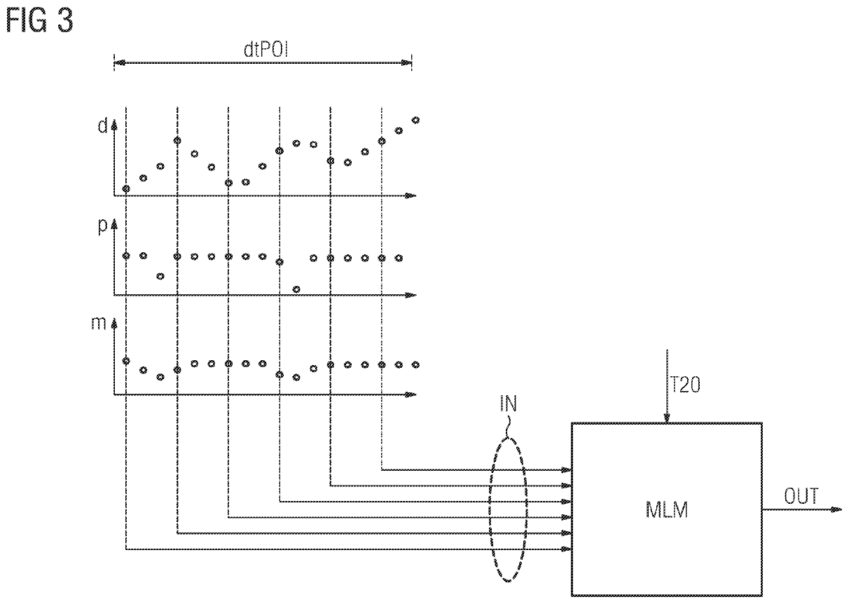

FIG. 3 now illustrates the input variables IN which are provided as illustrated in FIG. 2 and furthermore explains how they are provided for the section dtPOI of the path x as input variables IN for the trained machine learning model MLM. For the sake of clarity, in the present case only each third data point is included in the model MLM. As a rule, however, if the input variables IN are discretized to fit the model MLM, each data point should be included in the model MLM. Furthermore, the model MLM receives as an input variable a background temperature T20 that can originate, for example, from a superordinate thermal simulation. As an output variable OUT, the model MLM supplies a measurement for the process light E10, in other words for example the radiation intensity, the wavelength or a variable that does not have a dimension and is optimized for the further processing, said variable being for example a variable that is provided in a similar manner to a sensor value of a measurement of one of the radiation intensities and/or wavelengths.

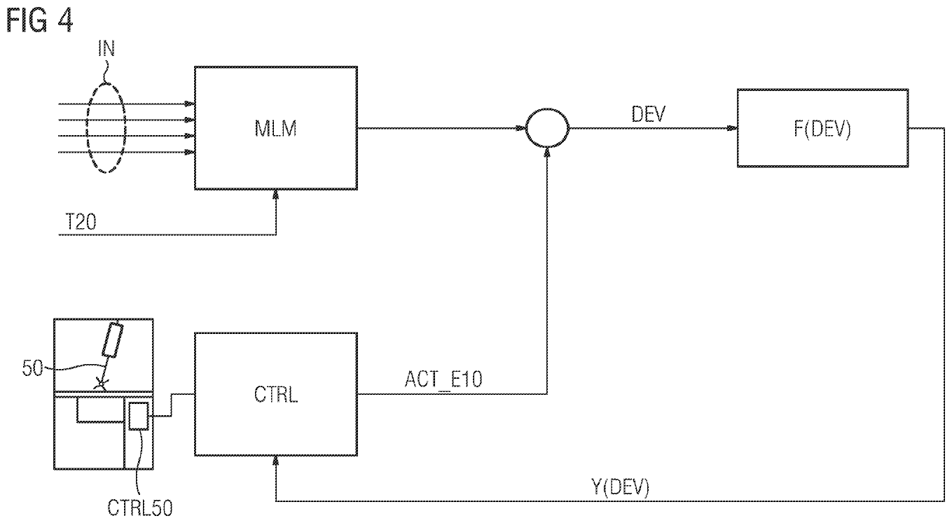

FIG. 4 illustrates one embodiment in which process deviations DEV of a melting process are determined by means of the machine learning model MLM that is known for example from FIG. 3. The input variables IN and the background temperature T20 are included in this case in the model. On the basis of this data, the trained machine learning model MLM generates a value for the process light E10 and consequently generates a target value SET_E10 for the process light. A process deviation DEV of the melting process is ascertained on the basis of the target value SET_E10 and an actual value of the process light ACT_E10.

In this case, for example, a controller CTRL of an energy beam installation 100 can provide the actual value ACT_E10. The energy beam installation 100 is illustrated in this case schematically and has an energy beam 50 and an energy beam controller CTRL50. In this case, the controller of the energy beam installation CTRL can also provide, in addition to the energy beam power, further variables and process parameters as input variables IN. It is likewise feasible that the input variables IN are provided by a further processing unit, which is integrated into the controller CTRL or is separate therefrom. The process deviation DEV is converted using a closed-loop control function F(DEV) into a control variable Y(DEV). In this case, the control variable Y(DEV) can be provided to the controller of the energy beam installation. In this case, the control variable Y(DEV) can be for example a laser beam power, a new timing between the vectors, a changed beam speed, a changed hatch spacing, etc.

To summarize, the teachings of the present disclosure include methods for determining a radiation intensity and/or a wavelength of a process light E10, methods for determining process deviations DEV of a melting process, and methods for the closed-loop control of a melting process. In order to improve the determination of a radiation intensity and/or a wavelength of process light of a melting process, a power profile P is proposed for a section dtPOI of the path x as an input variable IN for a machine learning model MLM, in particular for a neural network, wherein the model MLM is trained using historical and/or synthetic power profiles PH and associated historical or synthetic radiation intensities E10H and/or wavelengths of the process light E10 and to determine therefrom the radiation intensity and/or the wavelength of the process light E10 as an output variable OUT of the model MLM.

### LIST OF REFERENCE CHARACTERS

10 Melt pool

E10 Process light of the melt pool

20 Material

30 Material in powder form

50 Energy beam

100 Energy beam installation

x Path

POI Position

POI′ Start of the section

dtPOI Section

p Power profile in the section

d Distance history in the section

m Mass profile in the section

MLM Machine learning model

IN Input variable of the model

OUT Output variable of the model

T20 Background temperature as input variable of the model

DEV Process deviations of the melting process

SET_E10 Target value for the process light

ACT_E10 Actual value of the process light

F(DEV) Closed-loop control function

Y(DEV) Control variable

CTRL Controller of the energy beam installation

CTRL50 Controller of the energy beam

What is claimed is:

1. A method for determining a radiation intensity and/or a wavelength of a process light, wherein the melt pool underlying the process light can be generated by irradiating a metal material with an energy beam along a path, wherein the energy beam can be moved in accordance with a power profile along the path, the method comprising:
providing a power profile for a section of the path as an input variable for a machine learning model;
training the model using historical and/or synthetic power profiles and associated historical or synthetic radiation intensities and/or wavelengths of the process light for the metal material; and
determining the radiation intensity and/or the wavelength of the process light as an output variable of the model.

2. The method as claimed in claim 1, further comprising
providing for the model a distance history for the section as an input
wherein the distance history describes a distance between the section and the position at which the radiation intensity and/or the wavelength of the process light is to be determined.

3. The method as claimed in claim 1, further comprising
providing a mass profile as an input variable for the model for the section;
wherein the mass profile describes a mass of the material for each point on section.

4. The method as claimed in claim 1, further comprising
providing a background temperature as an input variable for the model which the material or the workpiece has outside the melt pool.

5. The method as claimed in claim 1, wherein the model has a topology having coefficients of regression.

6. The method as claimed in claim 1, further comprising
providing a volume element that is representative for the section as an input variable for the model.

7. The method as claimed in claim 1, further comprising
providing as an input variable for the model a workpiece geometry representative for the section.

8. The method as claimed in claim 1, wherein the section is selected so that at least one interruption of the energy beam is included.

9. The method as claimed in claim 1, wherein the section is selected in dependence upon a workpiece geometry.

10. A method for determining process deviations of a melting process, the method comprising:
providing a target value for a process light of a melt pool, wherein the target value depends on a radiation intensity determined using a method as claimed in claim 1;
detecting a radiation intensity, emitted by the melt pool and/or a wavelength of the process light as an actual value; and
comparing the target value with the actual value in order to detect process deviations.

11. The method as claimed in claim 10, further comprising weighting the relevance of the process deviation with the aid of classification parameters.

12. A method for closed-loop control of a melting process, wherein a process deviation determined using a method as claimed in claim 10 is reduced and/or eliminated by adapting one or multiple process parameters, in particular a beam power, a beam speed, a distance between individual exposure vectors.
